(19) United States
(12) Patent Application Publication
(10) Pub. No.: US 2026/0173890 A1
(43) Pub. Date: Jun. 18, 2026

(54) ELECTRONIC DEVICE AND MANUFACTURING METHOD THEREOF

(71) Applicant: Industrial Technology Research Institute, Hsinchu (TW)

(72) Inventors: Li-Wei Yao, Hsinchu County (TW); Tsung-Yen Hsieh, Miaoli County (TW); Yi-Rong Lin, Hsinchu City (TW); Shu-Wei Kuo, Hsinchu County (TW); Chung-Wei Wang, Hsinchu City (TW)

(73) Assignee: Industrial Technology Research Institute, Hsinchu (TW)

(21) Appl. No.: 18/985,033

(22) Filed: Dec. 18, 2024

(51) Int. Cl. H01L 23/60; H01L 23/00; H01L 23/367; H01L 23/498

(52) U.S. Cl. CPC H10W 42/60; H10W 40/22; H10W 70/65; H10W 72/00

(57) ABSTRACT

An electronic device, including a substrate, a shielding layer, an insulation layer, a circuit layer, and an electronic component, is provided. The substrate includes first, second, and third portions, wherein the first portion is lower than the second portion, and the third portion connects the second portion to the first portion to form a groove. The shielding layer is disposed on the first, second, and third portions. The insulation layer is disposed on the shielding layer. The circuit layer is disposed on the insulation layer. The electronic component is disposed in the groove and electrically connected to the circuit layer. The shielding layer disposed on the third portion laterally surrounds the electronic component. A manufacturing method of the electronic device is also provided.

### TECHNICAL FIELD

The disclosure relates to an electronic device and a manufacturing method thereof.

### BACKGROUND

Circuits and components in electronic devices are becoming more and more dense as the demand for functional diversity of electronic devices increases, causing mutual interference of electrical signals and resulting in poor reliability.

### SUMMARY

An electronic device and a manufacturing method thereof, which help to reduce mutual interference of electrical signals, are introduced herein.

An electronic device according to an embodiment of the disclosure includes a substrate, a shielding layer, an insulation layer, a circuit layer, and at least one electronic component. The substrate includes a first portion, a second portion, and a third portion. The first portion is lower than the second portion, and the third portion connects the second portion to the first portion to form a groove. The shielding layer is disposed on the first portion, the second portion, and the third portion. The insulation layer is disposed on the shielding layer. The circuit layer is disposed on the insulation layer. The at least one electronic component is disposed in the groove and is electrically connected to the circuit layer. The shielding layer disposed on the third portion laterally surrounds the at least one electronic component.

A manufacturing method of an electronic device according to an embodiment of the disclosure includes the following steps. A planar multilayer structure is formed. The planar multilayer structure includes a substrate and a shielding layer, an insulation layer, and a circuit layer sequentially stacked on the substrate. A forming process is performed on the planar multilayer structure to transform the planar multilayer structure into a non-planar multilayer structure having a groove. At least one electronic component is bonded to the circuit layer in the groove to be formed or already formed.

Several exemplary embodiments accompanied with drawings are described in detail below to further describe the disclosure in detail.

### BRIEF DESCRIPTION OF THE DRAWINGS

The accompanying drawings are included to provide a further understanding, and are incorporated in and constitute a part of this specification. The drawings illustrate exemplary embodiments and, together with the description, serve to explain the principles of the disclosure.

FIG. 1 is a partial top schematic view of an electronic device according to a first embodiment of the disclosure.

FIG. 2 is a cross-sectional schematic view corresponding to a section line I-I′ in FIG. 1.

FIG. 3A and FIG. 3B are respectively two enlarged schematic views of a region R in FIG. 2.

FIG. 4 is a partial cross-sectional schematic view of an electronic device according to a second embodiment of the disclosure.

FIG. 5 is a partial cross-sectional schematic view of an electronic device according to a third embodiment of the disclosure.

FIG. 6 is a partial top schematic view of an electronic device according to a fourth embodiment of the disclosure.

FIG. 7 is a cross-sectional schematic view corresponding to a section line II-II′ in FIG. 6.

FIG. 8 to FIG. 15 are respectively partial cross-sectional schematic views of various electronic devices according to a fifth embodiment to a twelfth embodiment of the disclosure.

FIG. 16 is a partial three-dimensional schematic view of an electronic device according to a thirteenth embodiment of the disclosure.

FIG. 17A to FIG. 17C and FIG. 18A to FIG. 18C are respectively flow schematic views of manufacturing methods of two electronic devices according to some embodiments of the disclosure.

### DETAILED DESCRIPTION OF DISCLOSURE EMBODIMENTS

Directional terms such as “upper”, “lower”, “front”, “rear”, “left”, and “right” mentioned in the embodiments are only directions with reference to the drawings. Therefore, the used directional terms are used to illustrate, but not to limit, the disclosure.

In the drawings, each drawing illustrates the general characteristics of a method, a structure, and/or a material used in a specific embodiment. However, the drawings should not be construed to define or limit the scope or nature covered by the embodiments. For example, the relative sizes, thicknesses, and positions of various film layers, regions, and/or structures may be reduced or enlarged for clarity.

In the embodiments, the same or similar components adopt the same or similar numerals, and redundant description thereof is omitted. In addition, features in different exemplary embodiments may be combined with each other without conflict, and simple equivalent changes and modifications made in accordance with the specification or the claims are still within the scope of the disclosure.

Terms such as “first” and “second” mentioned in the specification or the claims are only used to name different components or distinguish different embodiments or scopes, but are not used to limit the upper limit or the lower limit of the number of components, nor to define the manufacturing sequence or the disposition sequence of components. Furthermore, the disposition of a component/film layer on (or above) another component/film layer may include the case where an additional component/film layer is present or is not present between the two components/film layers. In other words, the component/film layer may be directly or indirectly disposed on (or above) the other component/film layer. On the other hand, the direct disposition of a component/film layer on (or above) another component/film layer means that the two components/film layers are in contact with each other and the additional component/film layer is not present between the two components/film layers.

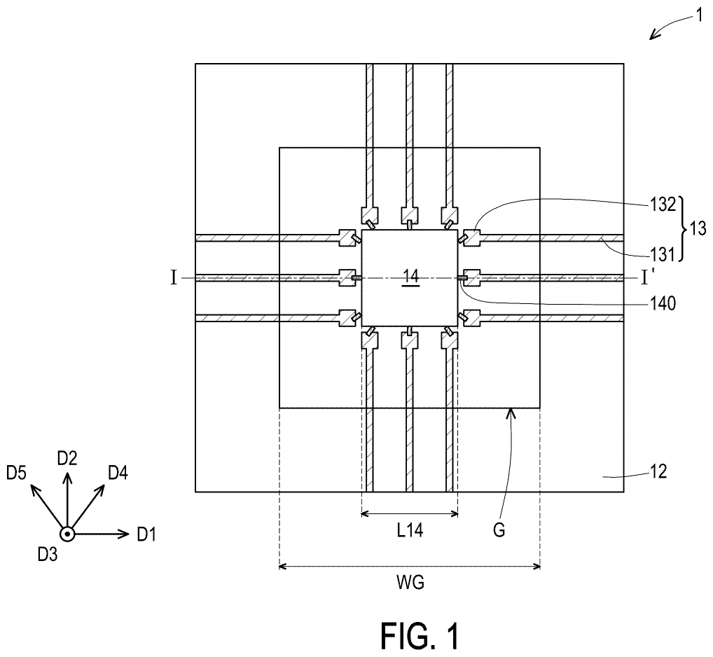

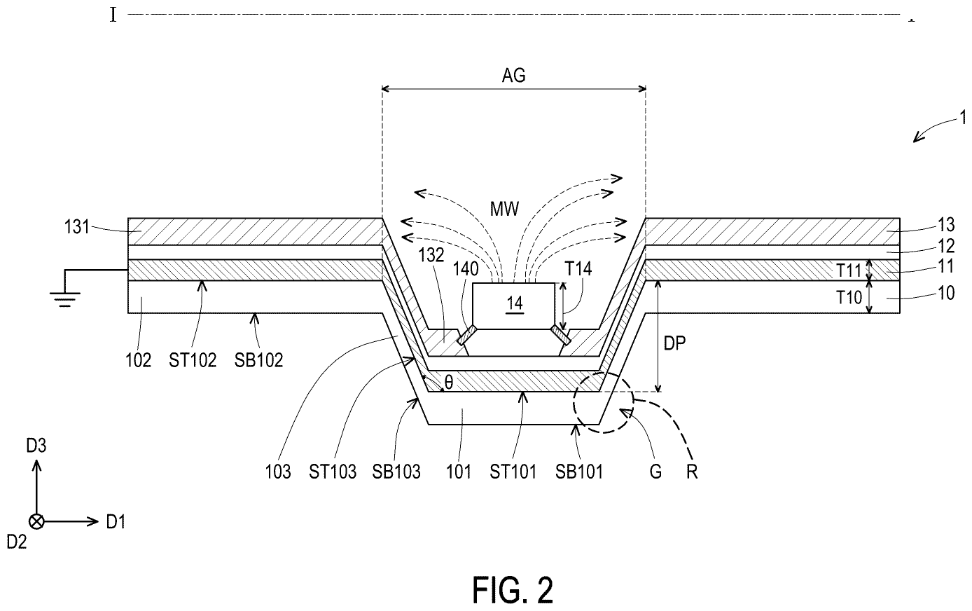

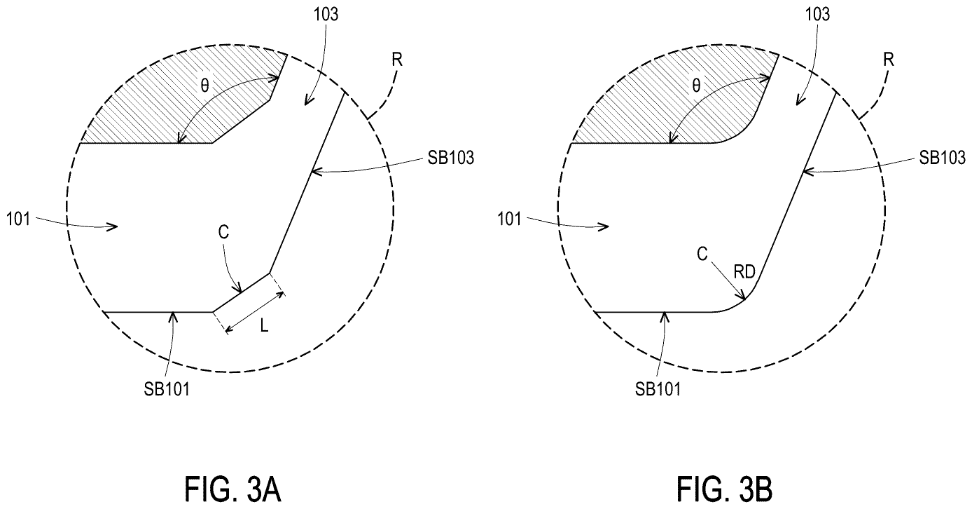

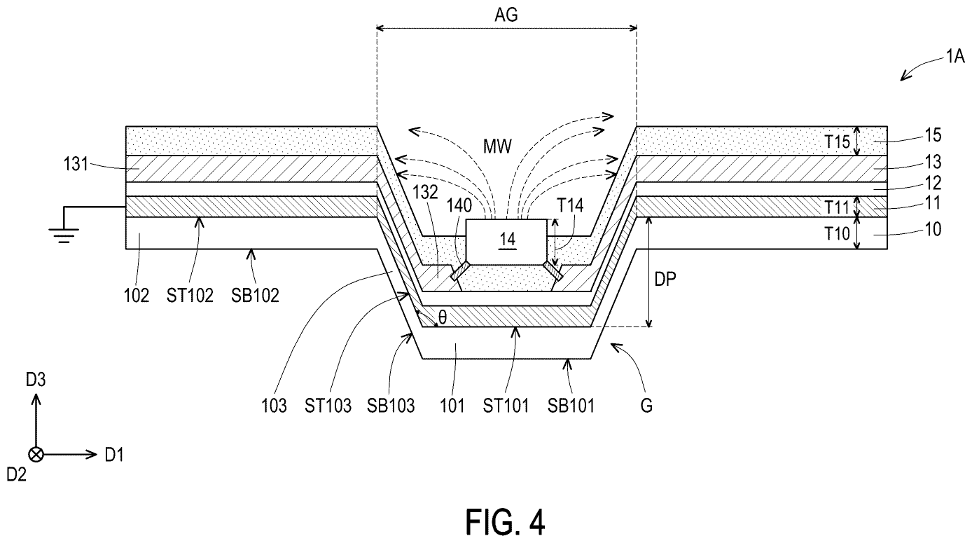

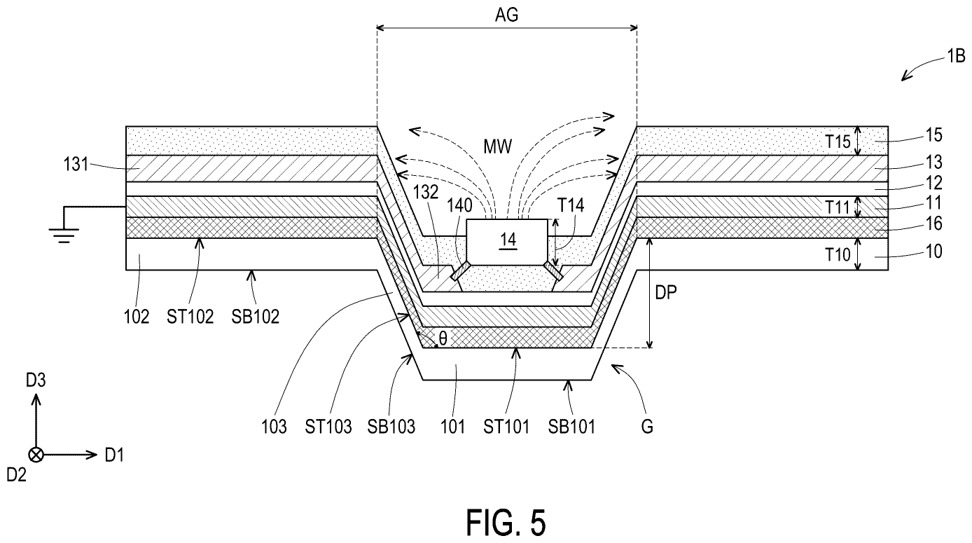

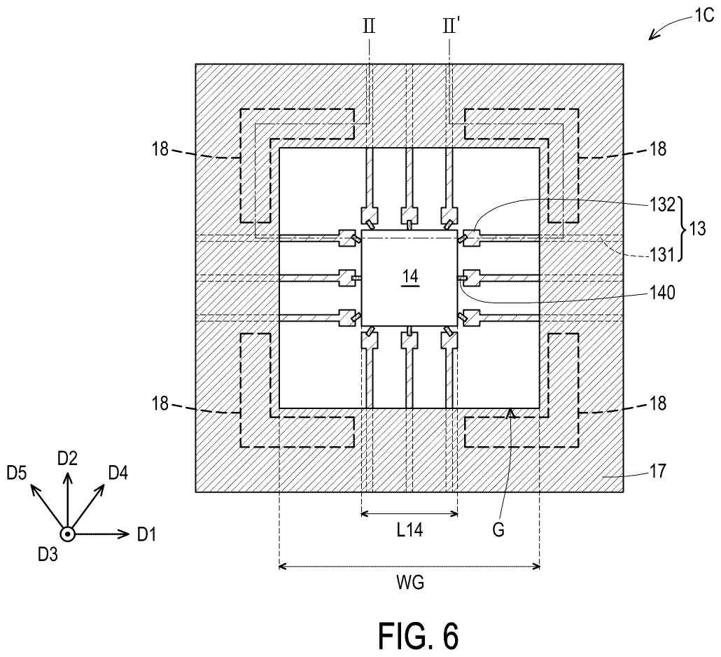

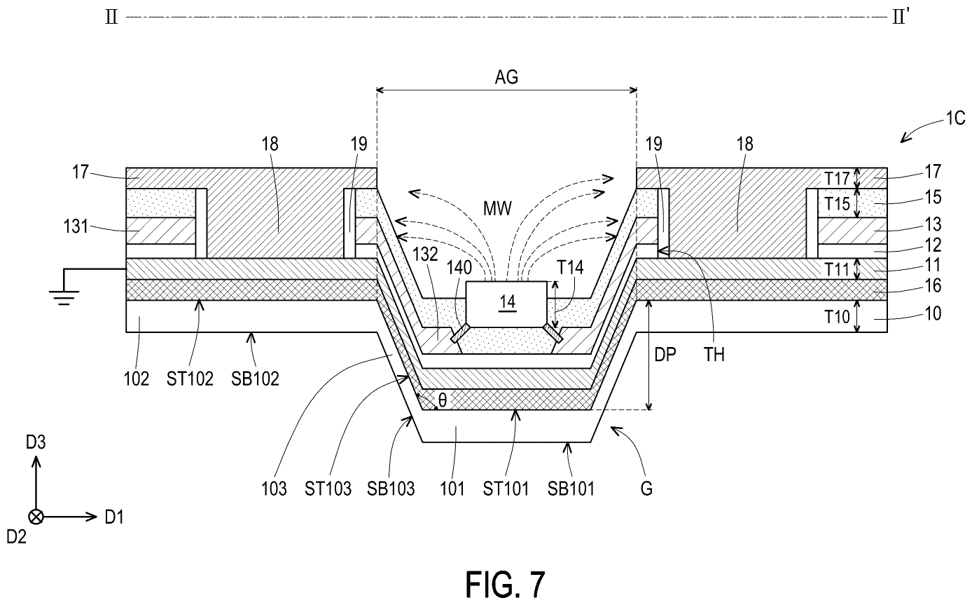

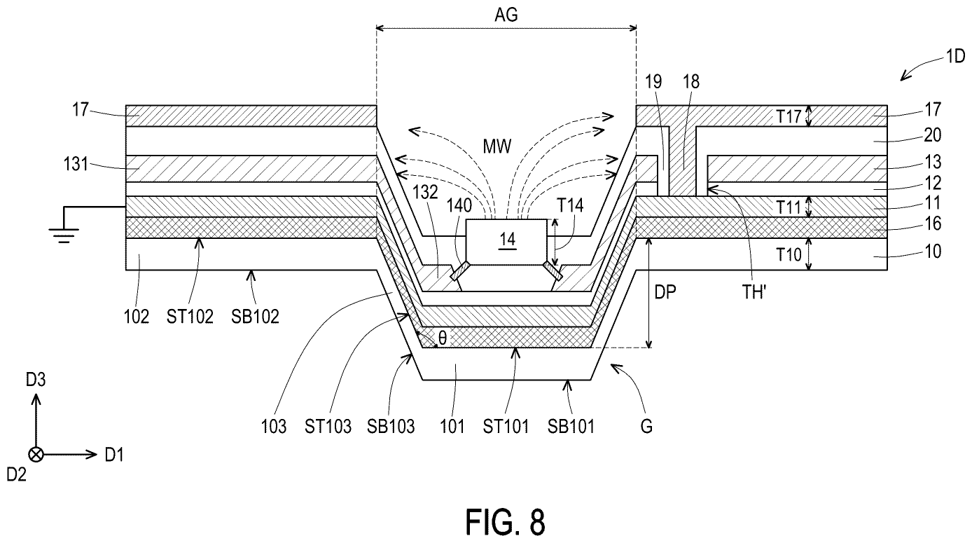

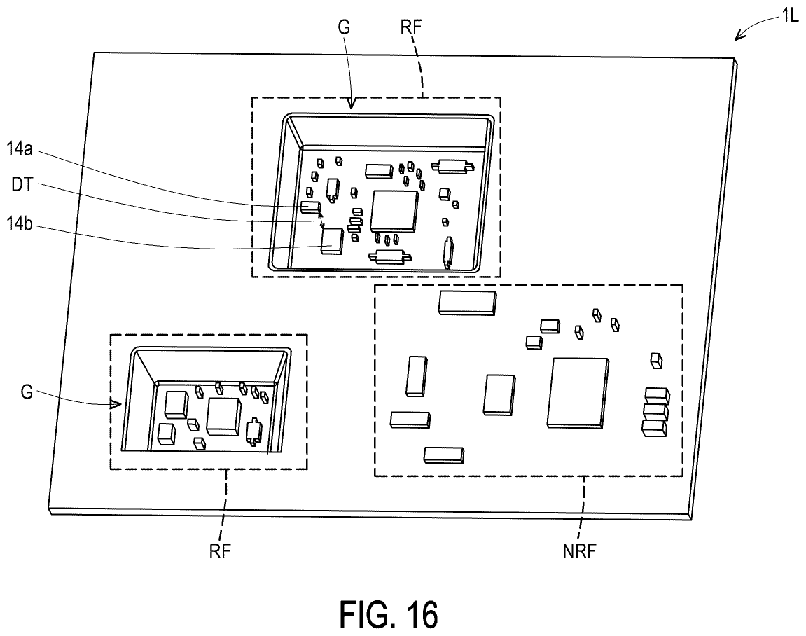

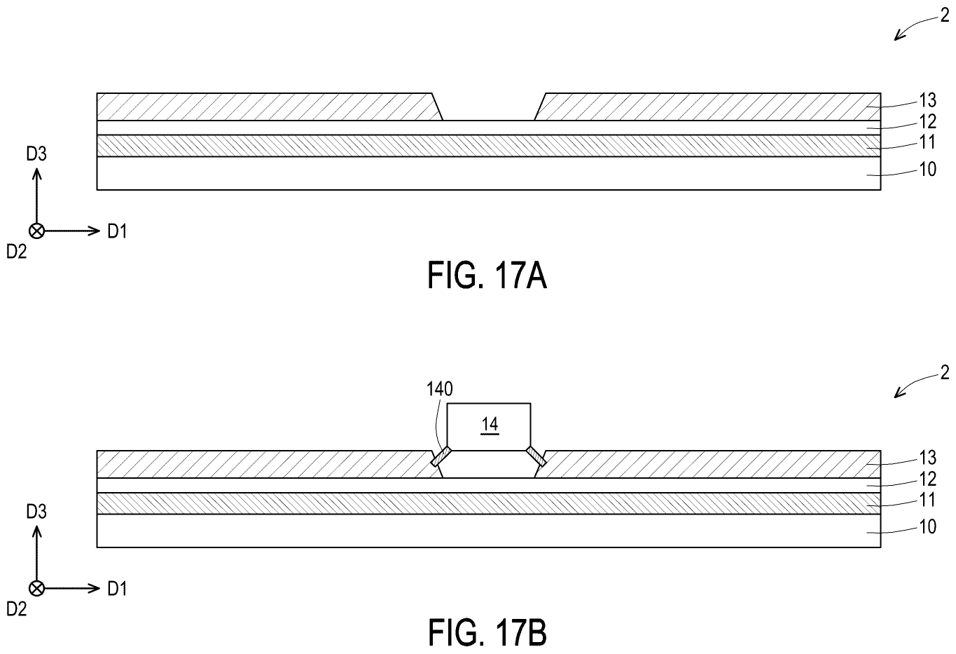

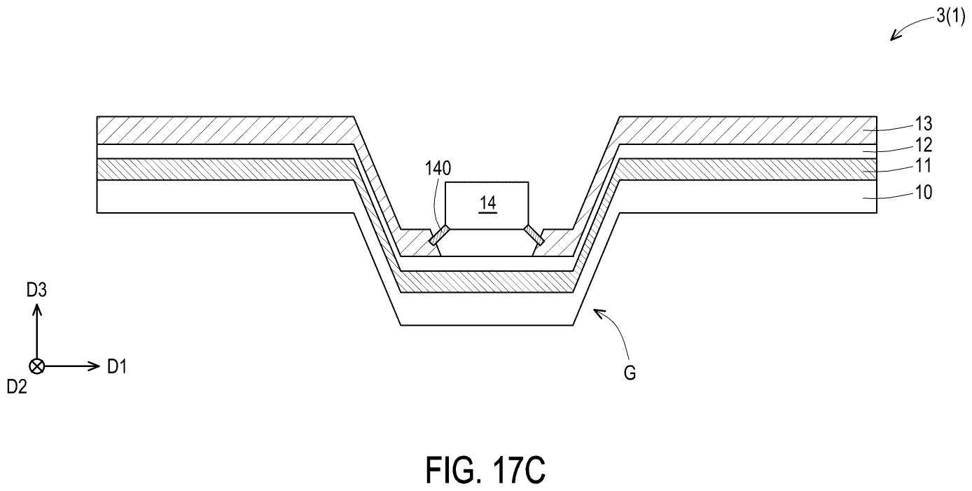

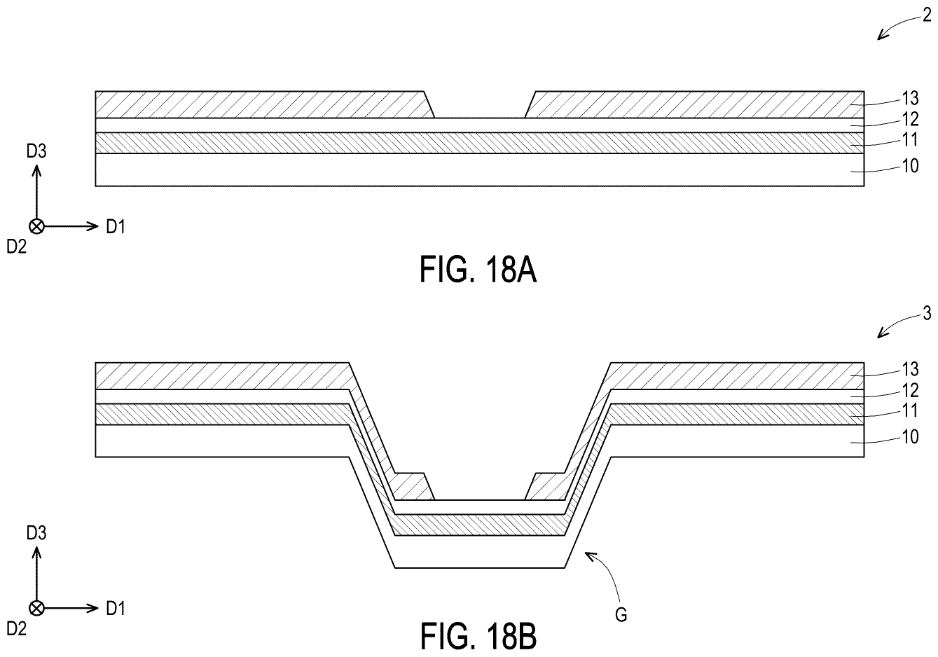

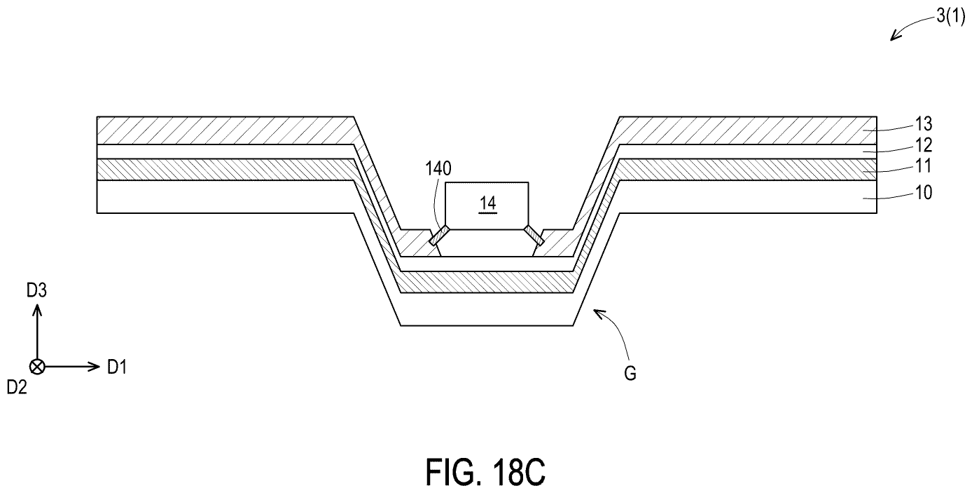

FIG. 1 is a partial top schematic view of an electronic device according to a first embodiment of the disclosure. FIG. 2 is a cross-sectional schematic view corresponding to a section line I-I′ in FIG. 1. FIG. 3A and FIG. 3B are respectively two enlarged schematic views of a region R in FIG. 2. FIG. 4 is a partial cross-sectional schematic view of an electronic device according to a second embodiment of the disclosure. FIG. 5 is a partial cross-sectional schematic view of an electronic device according to a third embodiment of the disclosure. FIG. 6 is a partial top schematic view of an electronic device according to a fourth embodiment of the disclosure. FIG. 7 is a cross-sectional schematic view corresponding to a section line II-II′ in FIG. 6. FIG. 8 to FIG. 15 are respectively partial cross-sectional schematic views of various electronic devices according to a fifth embodiment to a twelfth embodiment of the disclosure. FIG. 16 is a partial three-dimensional schematic view of an electronic device according to a thirteenth embodiment of the disclosure. FIG. 17A to FIG. 17C and FIG. 18A to FIG. 18C are respectively flow schematic views of manufacturing methods of two electronic devices according to some embodiments of the disclosure.

Please refer to FIG. 1 and FIG. 2 first. An electronic device 1 may include a substrate 10, a shielding layer 11, an insulation layer 12, a circuit layer 13, and at least one electronic component 14, but not limited thereto. The electronic device 1 may include other components or film layers according to different requirements.

Specifically, the substrate 10 is configured to carry the shielding layer 11, the insulation layer 12, the circuit layer 13, and the at least one electronic component 14. In some embodiments, a thickness T10 (for example, the maximum thickness in a thickness direction D3) of the substrate 10 may be greater than or equal to 0.1 mm and less than or equal to 5 mm, and the Young's modulus of the substrate 10 may be greater than or equal to 0.5 GPa and less than or equal to 20 GPa to facilitate stretching, compression, or shaping. For example, the material of the substrate 10 may include polyethylene terephthalate (PET), polyethylene terephthalate glycol (PETG), polycarbonate (PC), polyimide (PI), polymethyl methacrylate (PMMA, also referred to as acrylic), polyether styrene (PES), polydimethylsiloxane (PDMS), acrylonitrile-butadiene-styrene (ABS) copolymer, or a combination of the above, but not limited thereto.

As shown in FIG. 2, the substrate 10 may include a first portion 101, a second portion 102, and a third portion 103, wherein the first portion 101 is lower than the second portion 102, and the third portion 103 connects the second portion 102 to the first portion 101 to form a groove G. In some embodiments, as will be described later in FIG. 17A to FIG. 17C or FIG. 18A to FIG. 18C, an originally planar substrate may be shaped into a non-planar substrate (having the groove G) through a forming process (for example, thermoforming), so that a bottom surface SB101 of the first portion 101 (for example, a surface of the first portion 101 away from the shielding layer 11) is lower than a bottom surface SB102 of the second portion 102 (for example, a surface of the second portion 102 away from the shielding layer 11), and a top surface ST101 of the first portion 101 (for example, a surface of the first portion 101 facing the shielding layer 11) is lower than a top surface ST102 of the second portion 102 (for example, a surface of the second portion 102 facing the shielding layer 11), wherein a bottom surface SB103 of the third portion 103 (for example, a surface of the third portion 103 away from the shielding layer 11) connects the bottom surface SB101 of the first portion 101 to the bottom surface SB102 of the second portion 102, and a top surface ST103 of the third portion 103 connects the top surface ST101 of the first portion 101 to the top surface ST102 of the second portion 102.

The shielding layer 11 is disposed on the first portion 101, the second portion 102, and the third portion 103. In some embodiments, the shielding layer 11 is, for example, conformally disposed on the first portion 101, the second portion 102, and the third portion 103, so that in the cross-sectional view, as shown in FIG. 2, the shielding layer 11 may have a similar morphology to the substrate 10. For example, the shielding layer 11 is also formed with a groove (not labeled for the sake of simplicity of the drawing) that is conformal to the groove G.

The shielding layer 11 is, for example, configured to shield an electromagnetic wave MW. In some embodiments, the stretching ratio of the shielding layer 11 is greater than or equal to 20% to facilitate stretching, compression, or shaping. In some embodiments, although not shown, the shielding layer 11 may have a patterned structure to facilitate stretching, compression, or shaping. The patterned structure may include a grid structure, such as a vertical direction grid (including multiple thin lines extending along a direction D1 and multiple thin lines extending along a direction D2), a 45-degree direction grid (including multiple thin lines extending along a direction D4 and multiple thin lines extending along a direction D5), a zigzag direction grid, a solid diamond grid, a checkerboard grid, a dot grid, a random dot grid, a tile grid, a mesh grid, a fine mesh grid, a diagonal brick grid, a horizontal brick grid, a knitted grid, or grids in other forms, but not limited thereto.

In some embodiments, the resistivity of the shielding layer 11 may be greater than or equal to 10⁻⁸ Ω·m and less than or equal to 10⁻⁶ Ω·m to enhance electromagnetic wave shielding and/or provide electrostatic discharge (ESD) protection. In some embodiments, a thickness T11 (for example, the maximum thickness in the thickness direction D3) of the shielding layer 11 may be greater than or equal to 10 μm to enhance electromagnetic wave shielding and/or provide electrostatic discharge protection. For example, the shielding layer 11 may include metal particles (for example, gold, silver, platinum, copper, aluminum, nickel, etc.), metal oxide (for example, ferro ferrite as a magnetic filler), a carbon-based material (for example, carbon black, carbon fiber, graphene, carbon nanotubes), an MXene-based material (for example, an alternating stacked structure of multiple metal carbide layers and multiple carbon layers), etc., but not limited thereto.

The insulation layer 12 is disposed on the shielding layer 11. In some embodiments, the insulation layer 12 is, for example, conformally disposed on the shielding layer 11. Therefore, in the cross-sectional view, as shown in FIG. 2, the insulation layer 12 may also have a similar morphology to the substrate 10. For example, the insulation layer 12 is also formed with a groove (not labeled for the sake of simplicity of the drawing) that is conformal to the groove G.

The insulation layer 12 may be configured to electrically insulate the shielding layer 11 and the circuit layer 13. In some embodiments, the insulation layer 12 may be made of a material that is easy to stretch, compress, or shape, and the insulation layer 12 may have a high dielectric coefficient. For example, the dielectric coefficient is greater than or equal to 3.9, but not limited thereto. For example, the material of the insulation layer 12 may include a dielectric material such as acrylic, epoxy, phenol, polyester, urethane, silicone, and polyimide, but not limited thereto.

The circuit layer 13 is disposed on the insulation layer 12. In some embodiments, the circuit layer 13 is, for example, conformally disposed on the insulation layer 12. The circuit layer 13 may be configured to electrically connect the at least one electronic component 14 to other components (not shown in FIG. 1 and FIG. 2) or an external circuit (not shown in FIG. 1 and FIG. 2). For example, the material of the circuit layer 13 may include gold, silver, copper, aluminum, platinum, nickel, tin, carbon, an alloy of the above, or a combination of the above, but not limited thereto.

As shown in FIG. 1, the circuit layer 13 may include multiple wires 131 and multiple pads 132, wherein each wire 131 may extend into the groove G along the direction D1, the reverse direction of the direction D1, the direction D2, or the reverse direction of the direction D2 and be connected to the corresponding pad 132. As shown in FIG. 1, each pad 132 may be disposed at an end portion of the corresponding wire 131 adjacent to the at least one electronic component 14, but not limited thereto.

The at least one electronic component 14 is disposed in the groove G and is electrically connected to the circuit layer 13. For example, multiple pins 140 of the electronic component 14 may be respectively electrically connected to the pads 132 of the circuit layer 13. The electrical connection manner between the pin 140 and the corresponding pad 132 is not limited. For example, the pin 140 may be electrically connected to the corresponding pad 132 through wire bonding, flip-chip bonding, or other manners.

As shown in FIG. 2, the shielding layer 11 disposed on the third portion 103 laterally surrounds the at least one electronic component 14 disposed in the groove G, thereby providing electromagnetic wave shielding, such as shielding the electromagnetic wave MW generated by the at least one electronic component 14 from interfering with other electromagnetic wave sensitive components/electromagnetic wave generating components (not shown) and/or shielding electromagnetic waves generated by other electromagnetic wave sensitive components/electromagnetic wave generating components (not shown) from interfering with the at least one electronic component 14. In some embodiments, as shown in FIG. 2, the shielding layer 11 may be grounded. In some embodiments, the at least one electronic component 14 may include at least one electromagnetic wave sensitive component, such as a radio frequency (RF) component, an intermediate frequency (IF) component, a high frequency component, a power supply, a touch sensor, a low frequency component, a piezoelectric component, a light emitting diode (LED), an active component, a passive component, a buzzer, other electromagnetic wave generating components, or a combination of the above. FIG. 1 and FIG. 2 only schematically illustrate one electronic component 14, but it should be understood that the electronic device 1 may include multiple electronic components 14 according to requirements, and the types of the electronic components 14 may be the same or different.

Through forming the groove G and using the shielding layer 11 (also referred to as a three-dimensional shielding structure) disposed on a side wall surface of the groove G to shield an electromagnetic wave, the size and/or the weight of the electronic device 1 may be prevented from being increased, the impact of material shielding rate on electromagnetic wave shielding may be reduced, and/or the abilities of a 3D curved circuit to shield the electromagnetic wave and/or discharge static electricity are provided.

The larger the lateral shielding area of the shielding layer 11, the more enhanced the electromagnetic wave shielding. Under the architecture of FIG. 2, the greater the depth DP of the groove G, the greater the lateral shielding area of the shielding layer 11. In some embodiments, the depth DP of the groove G may be greater than or equal to 2 times the thickness T14 (for example, the maximum thickness in the thickness direction D3) of the electronic component 14, such as being greater than or equal to 5 times the thickness T14 of the electronic component 14 or greater than or equal to 10 times the thickness T14 of the electronic component 14 to enhance electromagnetic wave shielding.

Under the architecture of FIG. 2, the shielding layer 11 has a groove conformal to the groove G. An opening of the groove of the shielding layer 11 is proportional to an opening AG of the groove G. The narrower the opening AG, the less the leakage of the electromagnetic wave MW. In some embodiments, an included angle θ between the third portion 103 and the first portion 101 of the substrate 10 may be greater than or equal to 90 degrees and less than or equal to 110 degrees, such as being greater than or equal to 90 degrees and less than or equal to 100 degrees or greater than or equal to 90 degrees and less than or equal to 95 degrees to obtain the groove G with the narrow opening AG.

In some embodiments, as shown in FIG. 3A, a corner C between the third portion 103 and the first portion 101 may be a chamfer with a length L greater than or equal to 1 mm. Alternatively, as shown in FIG. 3B, the corner C between the third portion 103 and the first portion 101 may be a rounded chamfer with a radius RD greater than or equal to 1 mm to facilitate demolding.

In some embodiments, as shown in FIG. 1, a width WG of the groove G is greater than or equal to 1.5 times the length L14 of the at least one electronic component 14 to facilitate bonding of the at least one electronic component 14 and the circuit layer 13, such as reserving space for the part mounting process. The length L14 of the electronic component 14 refers to the length of the longer side of the electronic component 14 in the top view. Taking FIG. 1 as an example, the length L14 of the electronic component 14 is the length of the side of the electronic component 14 extending along the direction D1. The width WG of the groove G refers to the length of the side of the groove G corresponding to the longer side of the electronic component 14 in the top view.

The manufacturing method of the electronic device 1 may include the following steps. A planar multilayer structure 2 is formed. The planar multilayer structure 2 includes the substrate 10 and the shielding layer 11, the insulation layer 12, and the circuit layer 13 sequentially stacked on the substrate 10. A forming process is performed on the planar multilayer structure 2 to transform the planar multilayer structure 2 into a non-planar multilayer structure 3 having the groove G. The at least one electronic component 14 is bonded to the circuit layer 13 in the groove G to be formed or already formed, as shown in FIG. 17A to FIG. 17C or FIG. 18A to FIG. 18C.

FIG. 17A and FIG. 18A illustrate the planar multilayer structure 2 including the substrate 10, the shielding layer 11, the insulation layer 12, and the circuit layer 13. In some embodiments, the shielding layer 11, the insulation layer 12, and the circuit layer 13 may be formed on the substrate 10 through a screen printing process, but not limited thereto.

In some embodiments, as shown in FIG. 17B and FIG. 17C, the electronic component 14 may be bonded to the planar multilayer structure 2 first, and the groove G may be then formed through the forming process, wherein in FIG. 17B, the electronic component 14 is bonded to the circuit layer 13 in the groove G to be formed, so that after the forming process, as shown in FIG. 17C, the electronic component 14 is located in the groove G. The forming process may include a vacuum high-pressure thermoforming process or a vacuum blister forming process, but not limited thereto. In the embodiment shown in FIG. 17A to FIG. 17C, the electronic component 14 is bonded to the planar multilayer structure 2 before the forming process to form the groove G. Therefore, when forming the non-planar multilayer structure 3 having the groove G, the production of the electronic device 1 is preliminarily completed.

Alternatively, in the embodiment shown in FIG. 18A to FIG. 18C, the forming process is first performed to form the non-planar multilayer structure 3 having the groove G, and the electronic component 14 is then bonded to the circuit layer 13 in the formed groove G. In other words, the electronic component 14 is not bonded to the planar multilayer structure 2, but directly bonded to the non-planar multilayer structure 3 having the groove G, and the step of forming the non-planar multilayer structure 3 having the groove G (as shown in FIG. 18B) is before preliminarily completing the production of the electronic device 1 (as shown in FIG. 18C).

The electronic device according to any embodiment of the disclosure may be produced by adopting the process steps shown in FIG. 17A to FIG. 17C and/or FIG. 18A to FIG. 18C, which will not be repeated below.

Please refer to FIG. 4. The main difference between an electronic device 1A and the electronic device 1 in FIG. 2 is that electronic device 1A further includes a heat dissipation layer 15, wherein the heat dissipation layer 15 is disposed on the circuit layer 13, and the circuit layer 13 is located between the heat dissipation layer 15 and the shielding layer 11. In some embodiments, the heat dissipation layer 15 is, for example, conformally disposed on the circuit layer 13. For example, the planar multilayer structure 2 shown in FIG. 17A and FIG. 18A may further include the heat dissipation layer 15. The heat dissipation layer 15 along with the substrate 10, the shielding layer 11, the insulation layer 12, and the circuit layer 13 are formed together through a forming process to form the non-planar multilayer structure 3 having the groove G, and the at least one electronic component 14 may be bonded to the circuit layer 13 in the groove G to be formed or already formed.

In some embodiments, the thermal conductivity of the heat dissipation layer 15 may be greater than or equal to 6 W/m·K to improve heat dissipation. In some embodiments, the stretch ratio of the heat dissipation layer 15 may be greater than or equal to 20% to facilitate stretching, compression, or shaping. For example, the base material of the heat dissipation layer 15 may include thermoplastic polyurethane (TPU), thermoplastic polyester elastomer (TPEE), styrenic elastomer (TPS), or nylon 12 elastomer (PAE), and the heat dissipation layer 15 may be additionally added with boron nitride (BN), aluminum nitride (AlN), aluminum oxide (Al₂O₃), boron nitride carbon nanotubes (BNNT), or at least one of the above materials mixed in different proportions, but not limited to the single material above or a combination thereof.

In some embodiments, as shown in FIG. 4, the heat dissipation layer 15 may be in contact with the pin 140 or the heat sink (not shown) of the at least one electronic component 14 to spread heat outward through covering a heat source, thereby improving heat dissipation. In some embodiments, in the top view (not shown), the area of the heat dissipation layer 15 may be greater than or equal to 4 times the area of the at least one electronic component 14 disposed in the groove G to improve heat dissipation through spreading the heat outward. In some embodiments, a thickness T15 (for example, the maximum thickness in the thickness direction D3) of the heat dissipation layer 15 may be greater than or equal to 3/5 times (three fifths) the thickness T14 of the at least one electronic component 14, such as being greater than or equal to 2 times the thickness T14 of the at least one electronic component 14 to form heat convection and discharge the heat through increasing the contact area between the heat dissipation layer 15 and air.

Through forming the groove G and using the heat dissipation layer 15 disposed on the side wall surface of the groove G for heat dissipation, the heat may be spread outward, and the temperature difference between the heat source (for example, the electronic component 14) and the surrounding may be reduced, thereby helping to alleviate the issue of low operating efficiency of the electronic component 14 due to concentration of heat energy. If the electronic device 1A is further packaged through a packaging material (for example, plastic), the concentration of heat energy is slowed down through the design of the three-dimensional heat dissipation structure, and local appearance damage to the packaging material caused by the concentration of heat energy may be reduced, thereby improving the reliability and service life of the product.

Please refer to FIG. 5. The main difference between an electronic device 1B and the electronic device 1A in FIG. 4 is that the electronic device 1B further includes a decorative layer 16, wherein the decorative layer 16 is disposed between the substrate 10 and the shielding layer 11. In some embodiments, the decorative layer 16 is, for example, conformally disposed on the substrate 10. For example, the planar multilayer structure 2 shown in FIG. 17A and FIG. 18A may further include the decorative layer 16. The decorative layer 16 along with the substrate 10, the shielding layer 11, the insulation layer 12, the circuit layer 13, and the heat dissipation layer 15 are formed together through a forming process to form the non-planar multilayer structure 3 having the groove G, and the at least one electronic component 14 may be bonded to the circuit layer 13 in the groove G to be formed or already formed.

In some embodiments, in addition to providing a decorative effect (such as reducing the visibility of the circuit layer 13), the decorative layer 16 may further provide electromagnetic wave shielding. For example, the material of the decorative layer 16 may include carbon black or other non-conductive materials that may shield electromagnetic waves.

Please refer to FIG. 6 and FIG. 7. The main difference between an electronic device 1C and the electronic device 1B in FIG. 5 is that the electronic device 1C further includes a shielding layer 17, a shielding via 18, and an insulation layer 19, wherein the shielding layer 17 is disposed on the circuit layer 13, and the shielding via 18 penetrates the circuit layer 13 and the insulation layer 12 to electrically connect the shielding layer 11 to the shielding layer 17, and the shielding via 18 is electrically insulated from other film layers through the insulation layer 19.

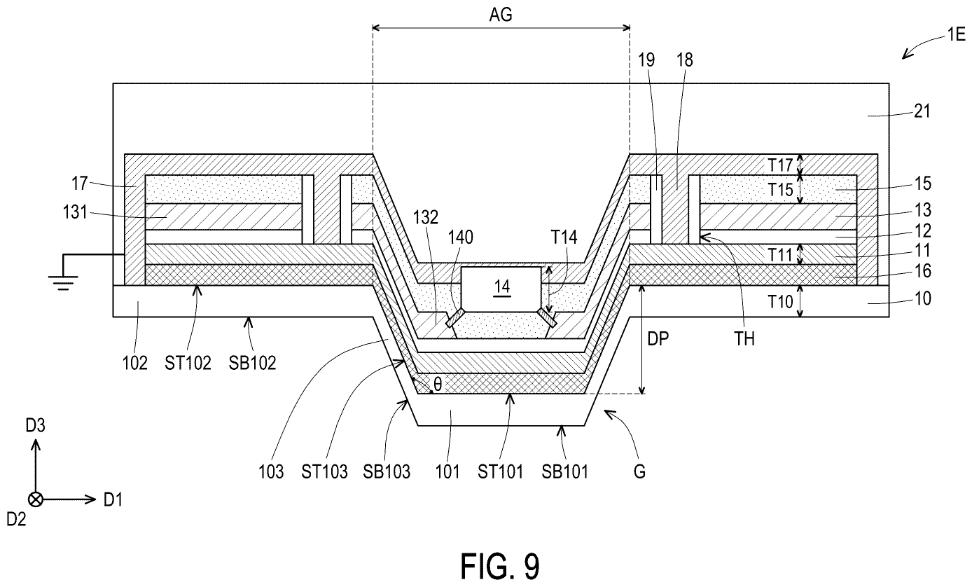

Specifically, under the architecture of the electronic device 1C including the heat dissipation layer 15, the shielding layer 17 may be disposed on the heat dissipation layer 15 and electrically insulated from the circuit layer 13 through the heat dissipation layer 15. In some embodiments, the shielding layer 17 and the shielding via 18 may be formed together, but not limited thereto. For example, a through hole TH penetrating the heat dissipation layer 15, the circuit layer 13, and the insulation layer 12 may be first formed, and the insulation layer 19 is then formed on a side wall of the through hole TH. Next, the shielding layer 17 is formed on the heat dissipation layer 15 and the shielding via 18 is formed in a space not occupied by the insulation layer 19 in the through hole TH. In some embodiments, as shown in FIG. 7, the shielding layer 17 may expose the electronic component 14 and the heat dissipation layer 15 overlapping with the groove G, but the disclosure is not limited thereto. In other embodiments, as shown in FIG. 9, the shielding layer 17 may cover the electronic component 14 and the heat dissipation layer 15 overlapping with the groove G.

Reference may be made to the description of the shielding layer 11 for details (for example, a patterned structure, the resistivity, a thickness T17, and/or the material, etc.) of the shielding layer 17, which will not be repeated here. Reference may be made to the description of the insulation layer 12 for details (for example, the dielectric coefficient, and/or the material, etc.) of the insulation layer 19, which will not be repeated here.

The planar multilayer structure 2 shown in FIG. 17A and FIG. 18A may further include the shielding layer 17, the shielding via 18, and the insulation layer 19. The shielding layer 17, the shielding via 18, and the insulation layer 19 along with the substrate 10, the decorative layer 16, the shielding layer 11, the insulation layer 12, the circuit layer 13, and the heat dissipation layer 15 are formed together through a forming process to form the non-planar multilayer structure 3 having the groove G, and the at least one electronic component 14 may be bonded to the circuit layer 13 in the groove G to be formed or already formed.

Through the setting of the shielding via 18, lateral shielding of the electromagnetic wave may be improved. FIG. 6 schematically illustrates four L-shaped shielding vias 18, but it should be understood that the design parameters (for example, the number, top view shapes, and/or positions, etc.) of the shielding vias 18 may be changed according to actual requirements, but are not limited to as shown in FIG. 6. For example, the shielding via 18 may be thicker or thinner; the number of the shielding vias 18 may be more or less; and/or the shielding vias 18 may be located on a single side, two adjacent sides, two opposite sides, three sides, four sides, etc. of the groove G. For example, although not shown, the shielding via 18 may be located between two adjacent grooves G or between the electronic component 14 and other electronic components.

Please refer to FIG. 8. The main difference between an electronic device 1D and the electronic device 1C in FIG. 7 is explained below. In the electronic device 1D, the heat dissipation layer 15 is replaced by an insulation layer 20. Reference may be made to the design parameters of the insulation layer 19 for the design parameters of the insulation layer 20, which will not be repeated here. In some embodiments, the insulation layer 20 and the insulation layer 19 may be formed together, but not limited thereto. For example, a through hole TH′ penetrating the circuit layer 13 and the insulation layer 12 may be first formed, and the insulation layer 20 and the insulation layer 19 may then be respectively formed on the circuit layer 13 and on a side wall of the through hole TH′, wherein the insulation layer 20 and the insulation layer 19 may be formed by the same process step. Next, the shielding layer 17 is formed on the insulation layer 20, and the shielding via 18 is formed in a space not occupied by the insulation layer 19 in the through hole TH′.

The planar multilayer structure 2 shown in FIG. 17A and FIG. 18A may further include the insulation layer 20. The insulation layer 20 along with the substrate 10, the decorative layer 16, the shielding layer 11, the insulation layer 12, the circuit layer 13, the shielding layer 17, the shielding via 18, and the insulation layer 19 are formed together through a forming process to form the non-planar multilayer structure 3 having the groove G, and the at least one electronic component 14 may be bonded to the circuit layer 13 in the groove G to be formed or already formed.

FIG. 8 schematically illustrates one shielding via 18 located on a single side of the groove G, but it should be understood that the design parameters (for example, the number, top view shapes, and/or positions, etc.) of the shielding vias 18 may be changed according to actual requirements, but are not limited to as shown in FIG. 8.

Please refer to FIG. 9. The main difference between an electronic device 1E and the electronic device 1C in FIG. 7 is explained below. The electronic device 1E further includes a packaging layer 21, wherein the packaging layer 21 is disposed on the shielding layer 17. The material of the packaging layer 21 may include plastic or other molding materials, and is not limited thereto. Although FIG. 9 further provides the packaging layer 21 under the architecture of FIG. 7, it should be understood that the electronic device of other embodiments of the disclosure may further include the packaging layer 21.

In some embodiments, the shielding layer 17 may overlap with the at least one electronic component 14. Under such an architecture, after forming the heat dissipation layer 15, the electronic component 14 may be bonded to the circuit layer 13 first, the insulation layer 19, the shielding layer 17, and the shielding via 18 are then formed (the shielding layer 17 and the shielding via 18 may be formed together), and a forming process is then performed to form the non-planar multilayer structure 3 having the groove G. Finally, the packaging layer 21 is formed through an injection process.

Through the design of the shielding layer 17 covering the electronic component 14, the interference of the electromagnetic wave (not shown) generated by the electronic component 14 to adjacent electronic components (not shown) may be reduced. The electronic device of other embodiments of the disclosure may also adopt the design of the shielding layer 17 covering the electronic component 14, which will not be repeated below.

In some embodiments, the shielding layer 17 may cover sidewalls of the decorative layer 16 (if any), the shielding layer 11, the insulation layer 12, the circuit layer 13, and the heat dissipation layer 15 (if any) to reduce the interference of adjacent electronic components (not shown) to the electronic component 14 in the groove G. The electronic device of other embodiments of the disclosure may also adopt such a design, which will not be repeated below.

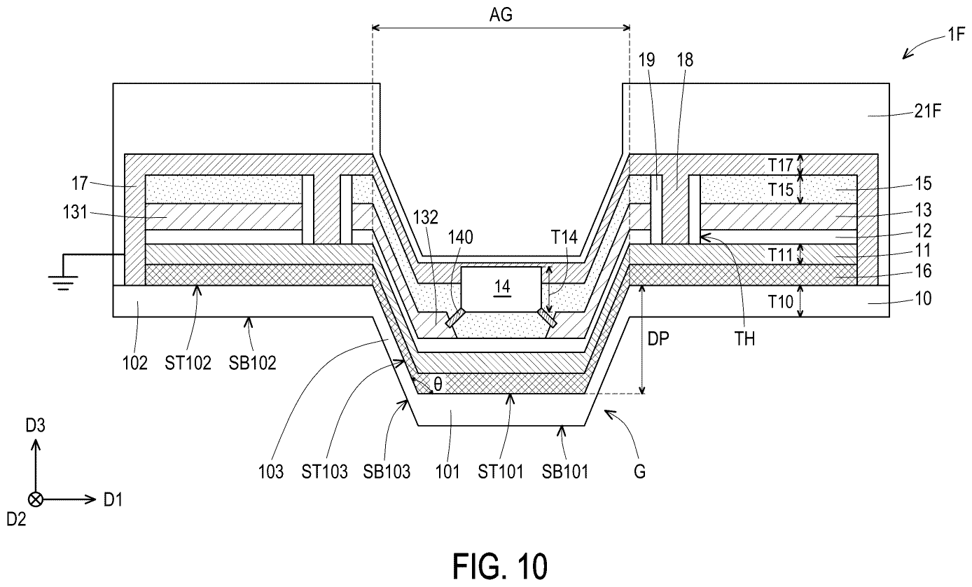

Please refer to FIG. 10. The main difference between an electronic device 1F and the electronic device 1E in FIG. 9 is that a part of a packaging layer 21F overlapping with the groove G is thinner than other parts of the packaging layer 21F. For example, the packaging layer 21F with different regional thicknesses may be formed through a male mold. Through the design of the packaging layer 21F with different regional thicknesses, thermal convection may be used to improve heat dissipation.

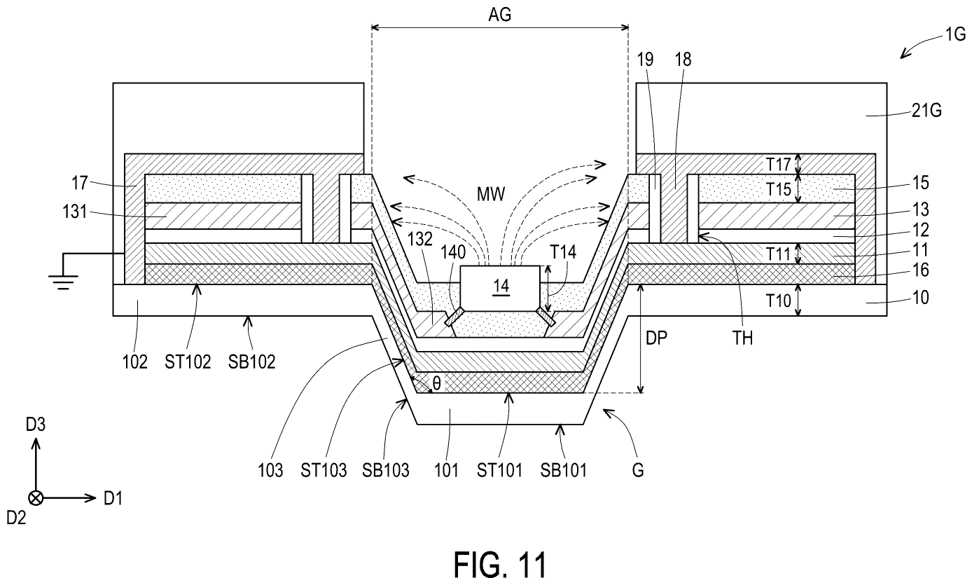

Please refer to FIG. 11. The main difference between an electronic device 1G and the electronic device 1F in FIG. 10 is that the shielding layer 17 and the packaging layer 21G expose the at least one electronic component 14. Taking FIG. 11 as an example, the shielding layer 17 and the packaging layer 21G may not overlap with the groove G, so that the heat dissipation layer 15 is in direct contact with the air, which helps to further improve heat dissipation. In addition, the design of the electronic component 14 not being covered by the shielding layer 17 and the packaging layer 21G may facilitate rework or replacement of the electronic component 14.

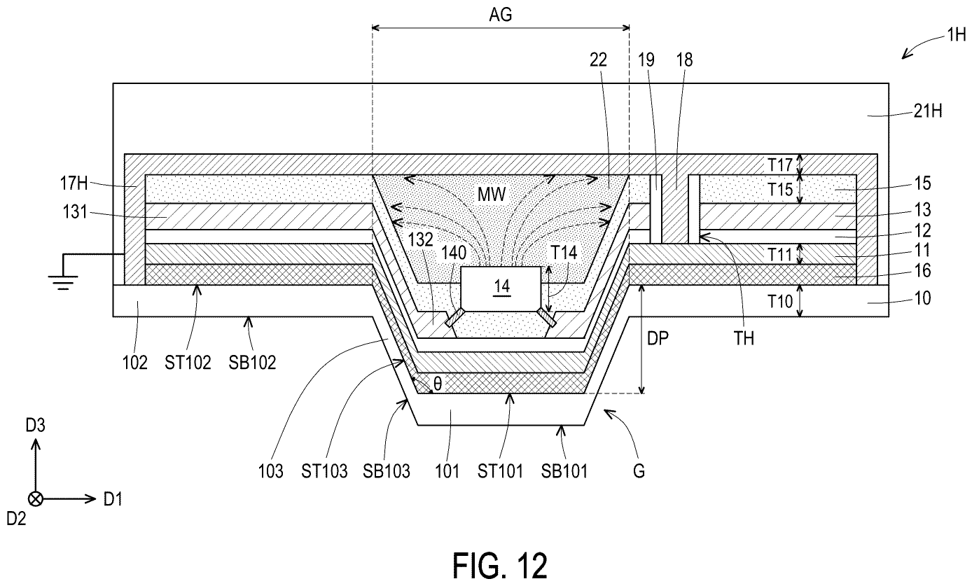

Please refer to FIG. 12. The main difference between an electronic device 1H and the electronic device 1F in FIG. 10 is that the electronic device 1H further includes a flat layer 22, wherein the flat layer 22 is disposed between the at least one electronic component 14 and a shielding layer 17H. For example, after forming the shielding via 18, the groove G may be first formed through a forming process (wherein the electronic component 14 may be bonded to the circuit layer 13 before or after the forming process), and the flat layer 22, the shielding layer 17H, and a packaging layer 21H may then be sequentially formed. In some embodiments, the material of the flat layer 22 may include a dielectric material such as acrylic, epoxy, phenol, polyester, urethane, silicone, and polyimide, and the flat layer 22 may be formed by potting, adhering, evaporation, sputtering, or a combination of the above, but not limited thereto. In addition, in FIG. 12, the shielding layer 17H may be formed by adopting a technique such as adhering, evaporation, sputtering, non-conductive vacuum metallization (NCVM), or a combination of the above, and the shielding layer 17H may be a metal film, a metal cover, a metal foil, a metal braided mesh, a conductive foam, a conductive cloth, etc., but not limited thereto.

Although FIG. 12 further provides the flat layer 22 and changes the design parameters (for example, the process manners, the materials, the appearances, etc.) of the shielding layer 17H and the packaging layer 21H under the architecture of FIG. 10, it should be understood that the electronic device of other embodiments of the disclosure may also be changed in the same way.

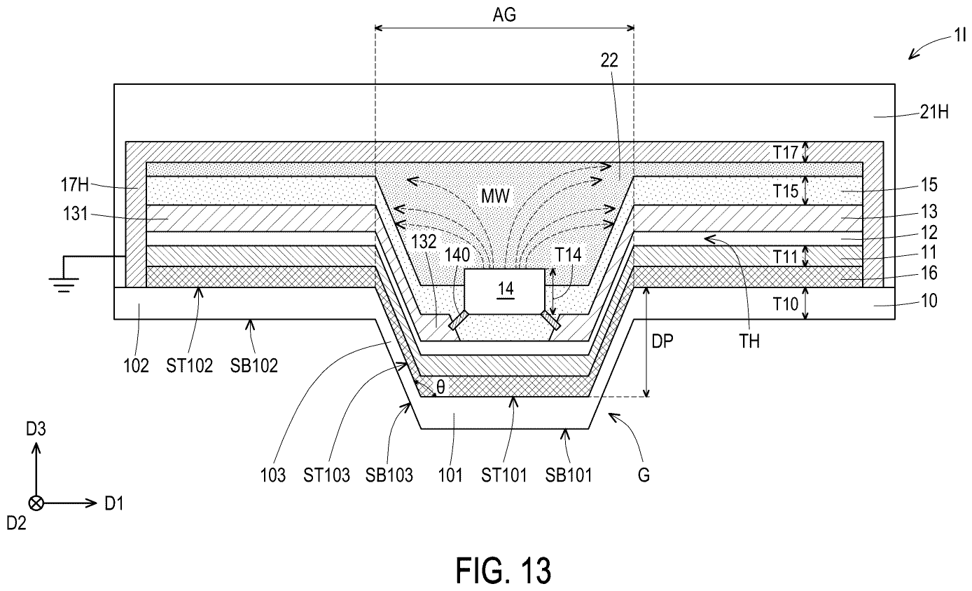

Please refer to FIG. 13. The main difference between an electronic device 1I and the electronic device 1H in FIG. 12 is that the flat layer 22 further extends between the heat dissipation layer 15 and a packaging layer 21H. In addition, the electronic device 1I omits the shielding via 18 and the insulation layer 19.

Although FIG. 13 further changes the design parameters (for example, the layout area, etc.) of the flat layer 22 under the architecture of FIG. 12, it should be understood that the electronic device of other embodiments of the disclosure may also be changed in the same way.

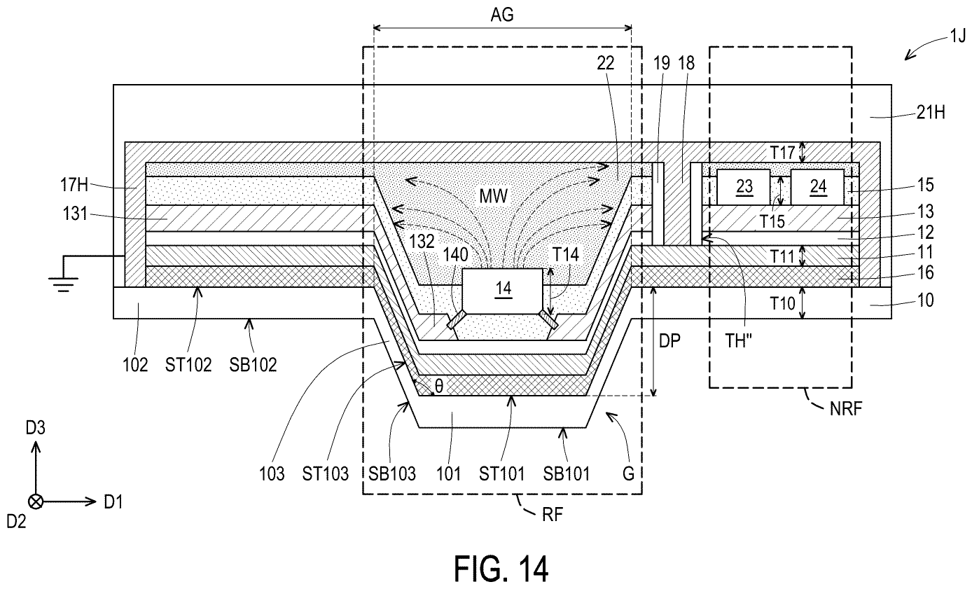

Please refer to FIG. 14. The main difference between an electronic device 1J and the electronic device 1I in FIG. 13 is that electronic device 1J further includes an electronic component 23 and an electronic component 24. The electronic component 23 and the electronic component 24 are disposed on the circuit layer 13 and are electrically connected to the circuit layer 13. In some embodiments, the electronic component 23 and the electronic component 24 may be disposed in a non-radio frequency circuit region NRF, and the electronic component 14 may be disposed in a radio frequency circuit region RF, wherein the non-radio frequency circuit region NRF and the radio frequency circuit region RF are separated by the shielding via 18, and the shielding via 18 and the insulation layer 19 are disposed in a through hole TH″ penetrating the flat layer 22, the heat dissipation layer 15, the circuit layer 13, and the insulation layer 12. The electromagnetic wave MW generated by the electronic component 14 located in the radio frequency circuit region RF is shielded or absorbed via the shielding layer 11 disposed on the side wall surface of the groove G, the shielding layer 17H disposed on the flat layer 22, and the shielding via 18 disposed between the non-radio frequency circuit region NRF and the radio frequency circuit region RF, which may reduce the interference of the electromagnetic wave MW to the electronic component 23 and the electronic component 24 located in the non-radio frequency circuit region NRF. For example, the electronic component 23 and the electronic component 24 may respectively be a light emitting diode and a resistor for controlling current to the light emitting diode, but not limited thereto. In other embodiments, the electronic component 23 and the electronic component 24 may be other types of electronic components.

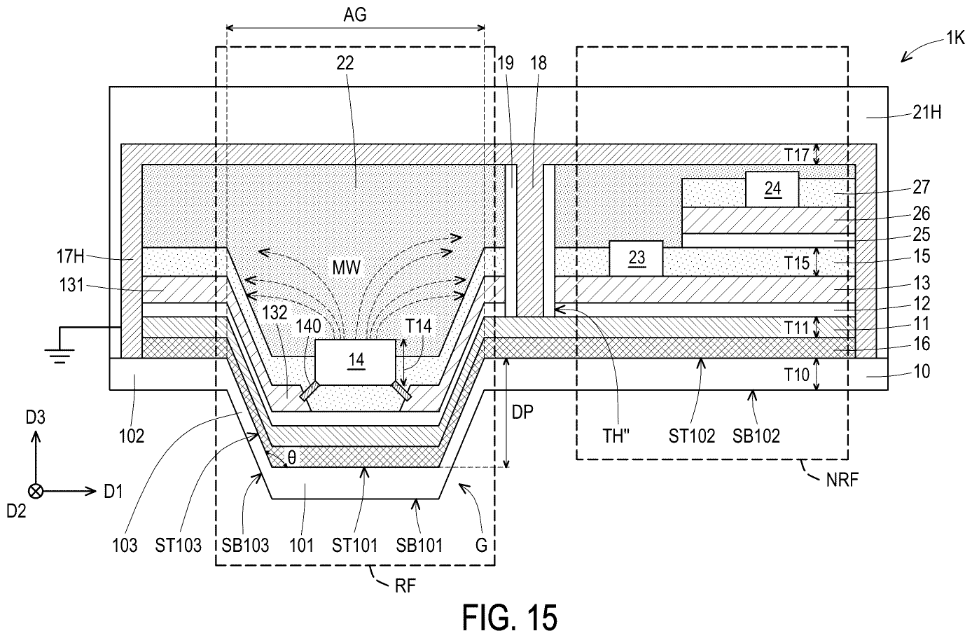

Please refer to FIG. 15. The main differences between an electronic device 1K and the electronic device 1J in FIG. 14 are explained below. In the electronic device 1K, the electronic component 23 and the electronic component 24 are respectively disposed on different circuit layers. For example, the electronic device 1K may further include an insulation layer 25, a circuit layer 26, and a heat dissipation layer 27, wherein the insulation layer 25, the circuit layer 26, and the heat dissipation layer 27 are sequentially stacked on the heat dissipation layer 15. Reference may be respectively made to the descriptions of the insulation layer 12, the circuit layer 13, and the heat dissipation layer 15 for details of the insulation layer 25, the circuit layer 26, and the heat dissipation layer 27, which will not be repeated here. The electronic component 23 and the electronic component 24 may be respectively disposed on the circuit layer 13 and the circuit layer 26, and the electronic component 23 and the electronic component 24 may be respectively in contact with the heat dissipation layer 15 and the heat dissipation layer 27. The flat layer 22 may cover the heat dissipation layer 15 and the heat dissipation layer 27.

Although FIG. 15 further changes the setting layers of the electronic component 23 and the electronic component 24 under the architecture of FIG. 14, it should be understood that the electronic device of other embodiments of the disclosure may also be changed in the same way.

In addition, although FIG. 15 is exemplified by two circuit layers (including the circuit layer 13 and the circuit layer 26), three insulation layers (including the insulation layer 12, the insulation layer 19, and the insulation layer 25), two heat dissipation layers (including the heat dissipation layer 15 and the heat dissipation layer 27), three electronic components (including the electronic component 14, the electronic component 23, and the electronic component 24), and one groove G, it should be understood that the electronic device 1K may include more circuit layers, more insulation layers, more heat dissipation layers, more electronic components, and more grooves G according to requirements. Taking FIG. 16 as an example, an electronic device 1L may include multiple grooves G, and each groove G defines one radio frequency circuit region RF. Multiple electronic components may be disposed in each groove G. For example, a first electronic component 14a and a second electronic component 14b may be disposed in the same groove G, and a distance DT (for example, the shortest distance) between the first electronic component 14a and the second electronic component 14b is, for example, greater than or equal to 10 mm to reduce the increase in surface temperature in the case where the heat source increases and/or alleviate the issue of local appearance damage to the packaging material (for example, the packaging layer 21H) caused by the concentration of heat energy, thereby improving the reliability and service life of the product.

In summary, in the embodiments of the disclosure, the electromagnetic wave is shielded through the design of the three-dimensional shielding structure, which may reduce mutual interference of electrical signals, prevent increasing the size and/or the weight of the electronic device, reduce the impact of material shielding rate on electromagnetic wave shielding, and/or provide the abilities of the 3D curved circuit to shield the electromagnetic wave and/or discharge static electricity. Optionally, the concentration of heat energy may also be slowed down through the design of the three-dimensional heat dissipation structure, and local appearance damage to the packaging material caused by the concentration of heat energy may be reduced, thereby improving the reliability and service life of the product.

It will be apparent to those skilled in the art that various modifications and variations may be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An electronic device, comprising:
a substrate, comprising a first portion, a second portion, and a third portion, wherein the first portion is lower than the second portion, and the third portion connects the second portion to the first portion to form a groove;
a shielding layer, disposed on the first portion, the second portion, and the third portion;
an insulation layer, disposed on the shielding layer;
a circuit layer, disposed on the insulation layer; and
at least one electronic component, disposed in the groove and electrically connected to the circuit layer, wherein the shielding layer disposed on the third portion laterally surrounds the at least one electronic component.

2. The electronic device according to claim 1, wherein a depth of the groove is greater than or equal to 2 times a thickness of the electronic component.

3. The electronic device according to claim 1, wherein an included angle between the third portion and the first portion is greater than or equal to 90 degrees and less than or equal to 110 degrees.

4. The electronic device according to claim 1, wherein a corner between the third portion and the first portion is a chamfer with a length greater than or equal to 1 mm or a rounded chamfer with a radius greater than or equal to 1 mm.

5. The electronic device according to claim 1, wherein a thickness of the substrate is greater than or equal to 0.1 mm and less than or equal to 5 mm, and a Young's modulus of the substrate is greater than or equal to 0.5 GPa and less than or equal to 20 GPa.

6. The electronic device according to claim 1, wherein a stretch ratio of the shielding layer is greater than or equal to 20%, and a resistivity of the shielding layer is greater than or equal to 10⁻⁸ Ω·m and less than or equal to 10⁻⁶ Ω·m.

7. The electronic device according to claim 1, wherein the at least one electronic component comprises at least one electromagnetic wave sensitive component.

8. The electronic device according to claim 1, wherein the at least one electronic component comprises a first electronic component and a second electronic component, and a distance between the first electronic component and the second electronic component is greater than or equal to 10 mm.

9. The electronic device according to claim 1, further comprising:
a heat dissipation layer, disposed on the circuit layer, wherein the circuit layer is located between the heat dissipation layer and the shielding layer.

10. The electronic device according to claim 9, wherein a thermal conductivity of the heat dissipation layer is greater than or equal to 6 W/m·K.

11. The electronic device according to claim 9, wherein:
the heat dissipation layer is in contact with a pin or a heat sink of the at least one electronic component,
in a top view, an area of the heat dissipation layer is greater than or equal to 4 times an area of the at least one electronic component disposed in the groove, and
a thickness of the heat dissipation layer is greater than or equal to 3/5 times a thickness of the at least one electronic component.

12. The electronic device according to claim 1, further comprising:
another shielding layer, disposed on the circuit layer; and
a shielding via, penetrating the circuit layer and the insulation layer to electrically connect the shielding layer to the another shielding layer.

13. The electronic device according to claim 12, further comprising:
a packaging layer, disposed on the another shielding layer.

14. The electronic device according to claim 13, wherein the another shielding layer and the packaging layer overlap with the at least one electronic component, and a part of the packaging layer overlapping with the groove is thinner than other parts of the packaging layer.

15. The electronic device according to claim 13, wherein the another shielding layer and the packaging layer expose the at least one electronic component.

16. The electronic device according to claim 12, wherein the another shielding layer completely covers the at least one electronic component, and the electronic device further comprises:
a flat layer, disposed between the at least one electronic component and the another shielding layer.

17. The electronic device according to claim 1, wherein a width of the groove is greater than or equal to 1.5 times a length of the at least one electronic component.

18. A manufacturing method of an electronic device, comprising:
forming a planar multilayer structure, wherein the planar multilayer structure comprises a substrate and a shielding layer, an insulation layer, and a circuit layer sequentially stacked on the substrate;
performing a forming process on the planar multilayer structure to transform the planar multilayer structure into a non-planar multilayer structure having a groove; and
bonding at least one electronic component to the circuit layer in the groove to be formed or already formed.

19. The manufacturing method of the electronic device according to claim 18, wherein a method of forming the shielding layer, the insulation layer, and the circuit layer on the substrate comprises a screen printing process.

20. The manufacturing method of the electronic device according to claim 18, wherein the forming process comprises a vacuum high-pressure thermoforming process or a vacuum blister forming process.
